(19) United States
(12) Patent Application Publication
(10) Pub. No.: US 2004/0252560 A1
(43) Pub. Date: Dec. 16, 2004

(54) Multifunctional flash memory drive

(75) Inventor: Hsiang-An Hsieh, Hsindien City (TW)

Correspondence Address: TROXELL LAW OFFICE PLLC, SUITE 1404, 5205 LEESBURG PIKE, FALLS CHURCH, VA, 22041, US

(73) Assignee: Carry Computer Eng. Co., Ltd.

(21) Appl. No.: 10/639,505

(22) Filed: Aug. 13, 2003

(30) Foreign Application Priority Data
Jun. 13, 2003 (TW) 092210882

(51) Int. Cl. G11C 7/00

(52) U.S. Cl. 365/199

(57) ABSTRACT

The present invention provides a multifunctional flash memory drive mainly comprising a main body and an expansion slot for flash memory card; said flash memory drive is designed into a form similar to an U-disk, and the main body has a transmission interface similar to an USB or IEEE1394 plug at an appropriate position to connect to the external equipment end to access data; said expansion slot on the main body is designed to use with one or a plurality of external memory cards to expand the storage capacity; said main body has a circuit board electrically connected to said transmission interface and expansion slot; said circuit board has a main controller, which may play digital audio (MP3, WMV, etc.) and/or detect and determine the type of the memory cards inserted in said expansion slot and/or process signals transmitted between said transmission interface and said external equipment end. In that way, said flash memory drive achieves multi functions.

### FIELD OF THE INVENTION

The present invention relates to a multifunctional flash memory drive that supports a wide range of memory cards, in particular a multifunctional flash memory drive that is designed on a main body with a standard USB/IEEE1394 interface and audio recording and playing function.

### BACKGROUND OF THE INVENTION

Due to the advantages of flash memory cards, such as low power consumption, high reliability, large capacity, and fast access speed, there is a trend that flash memory cards will substitute diskettes and CDs and become important media used with IA products.

Currently, there are mainly 2 types of storage media for flash memory products: memory card and USB U-disk, wherein memory cards (e.g., PCMCIA cards, CF cards, SM cards, MMC cards, SD cards, MS cards, and XD cards) are mainly used in digital products such as digital cameras, digital video cameras, and PDAs; USB U-disks (e.g., memory sticks) are mainly used in PCs to enhance portability. Both of the 2 types of storage media have their respective supporters in the market.

However, both above memory cards and USB U-disks utilize embedded flash memories with fixed capacity, hence it is impossible to expand memory for them, resulting limitation to storage capacity. Moreover, they only have simple storage function, without audio playing and recording function or other functions. In today's world where people focus on diverse functions and amusement feature, they are unsatisfying.

Recently, USB U-disks with MP3 player function are available in the market. Such an USB disk has a main body with an USB plug, and the main body has a circuit board with a controller and a flash memory. Said controller supports recording and playing digital audio (MP3, WMV), thus the USB U-disk may play or record audio content at any time. However, the capacity of flash memory used to store audio content is fixed, which limits the storage capacity. A type of adapting device with an USB plug has appeared in the market. Said adapting device has an internal circuit board, which is electrically connected to the USB plug. The characteristics of said adapting device is that the main body has a socket electrically connected to the circuit board, and an external memory card may be inserted in said socket. Thus the data stored in said memory card may be transferred to the system end through the USB plug. However, such an adaptor only delivers adapting function instead of storage or other functions.

Therefore, it is urgent task to integrate above USB U-disk (with MP3 recording and playing function) with a portable device supporting external memory cards into a multifunctional device that is not limited to embedded storage capacity or specific memory card specifications.

### SUMMARY OF THE INVENTION

In consideration of above problems, the inventor provides a multifunctional flash memory drive through laborious study and tests to facilitate information portability.

An object of the present invention is to provide a multifunctional flash memory drive comprising a main body similar to an U-disk and an expansion slot in the main body. There is a transmission interface at an appropriate position on the main body, and said transmission interface may be coupled to an external equipment end. The main body has a circuit board electrically connected to said transmission interface and said expansion slot, wherein: said main body has an insertion end at one end, said insertion end extends towards the other end of the main body to form an enclosed space. A plurality of sockets are formed in a stack way in the direction vertical to said extension plane to accommodate memory cards of different specifications, in order to expand data storage capacity.

Another object of the invention is to utilize a main controller on the circuit board to record and play digital audio (MP3, WMV) and/or detect the types of the memory cards inserted in the expansion slot; through the expansion slot supporting a wide range of memory cards, the main body capable of recording and playing digital audio may record audio content in the memory cards inserted in said expansion slot or play audio content stored in said memory cards.

Wherein, the multifunctional flash memory drive capable of recording and playing audio (MP3, FM) may be equipped with a separate power supply unit, which may deliver power to said flash memory drive when it is connected to said flash memory drive.

In addition, said multifunctional flash memory drive may have an embedded storage medium (e.g., flash memory) to enhance data storage.

To understand better above objects and other objects, features, and advantages of the present invention, hereunder we will describe in detail the invention in the following embodiments, with reference to the attached drawings.

### BRIEF DESCRIPTION OF THE DRAWINGS

FIG. 1A and FIG. 1B are the front view and the side view of a preferred embodiment of the multifunctional flash memory drive described in the present invention, respectively.

FIG. 1C is a sketch diagram of the internal circuit of the multifunctional flash memory drive shown in FIG. 1A and FIG. 1B.

FIG. 2A and FIG. 2B show another preferred embodiment of the multifunctional flash memory drive attached to/detached from a separate power supply unit.

FIG. 2C is a sketch diagram of the internal circuit of the multifunctional flash memory drive shown in FIG. 2A and FIG. 2B.

1: Multifunctional Flash Memory Drive

10: Main Body

110: Circuit Board

1110: Main Controller

1112: Bridging Module

1114: Detecting and Determining Module

1116: Audio Recording and Playing Module

1120: Embedded Flash Memory

112: Insertion End

114: MMI & Wireless Remote Control Interface

116: Microphone

118: Transmission Interface

119: Earphone Seat

12: Expansion Slot

121, 122, 123: Socket

16: PC System

160: Interface Socket

34: Separate Power Supply Unit

342: Battery Cartridge

344: Seat

3440: Interface Socket

346: Guide Groove

### EMBODIMENTS OF THE INVENTION

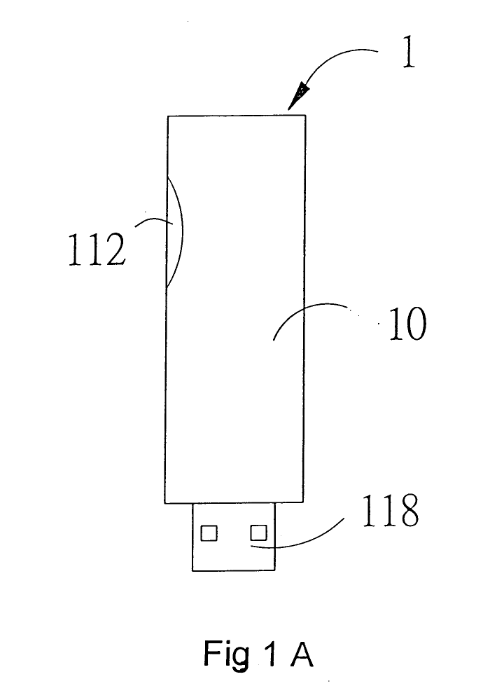

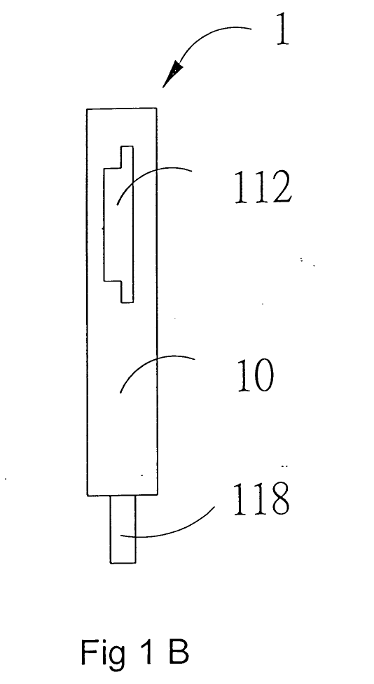

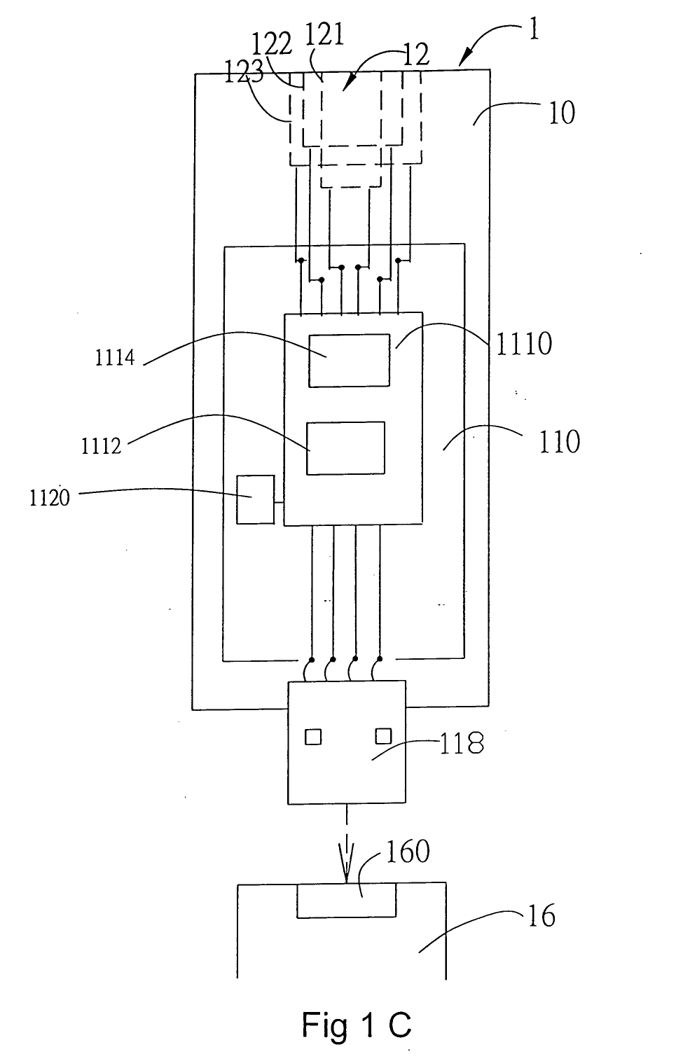

Please see FIG. 1A˜1C, a preferred embodiment of multifunctional flash memory drive 1 implemented according to the invention. The multifunctional flash memory drive 1 comprises a main body 10 with a transmission interface 118 and an expansion slot 12 (as shown in FIG. 1C), wherein said main body 10 is similar to an U-disk in appearance for portability; the transmission interface 118 is located at an appropriate position on the main body 10 and may be an USB interface, IEEE1394 interface, or any high-speed transmission interface. Moreover, the transmission interface 118 may be designed into a plug form to be connected directly to an external equipment end (e.g., the PC system 16 shown in FIG. 1C) to exchange data between them.

To enable the main body 10 to support a wide range of memory cards, an insertion end 112 is devised at one end of the main body 10, please see the front view of the multifunctional flash memory drive 1 in FIG. 1A and the side view of the multifunctional flash memory drive 1 in FIG. 1B. In addition, the insertion end 112 may also be devised on the main body 10, as shown in FIG. 1C. No matter where the insertion end 112 may be, it extends from its opening towards the opposite side of the main body in horizontal direction (X axis) to form an enclosed space. An expansion slot 12 comprising a plurality of sockets (e.g., socket 121, 122, 123 in FIG. 1C) are devised in stack form in the direction vertical to said enclosed space (Z axis) to accommodate external memory cards of different specifications (e.g., MS series, SD card, MMC card, SM card, XD card, or other mini memory cards). Due to the fact that those memory cards are different both in length and width, the expansion slot 12 is designed in an echelon-form insertion port in its width direction (Y axis) to adapt to those memory cards, as shown in FIG. 1B, thus the multifunctional flash memory drive may support a wide range of mini memory cards.

Please see FIG. 1C, wherein the main body 10 has a circuit board 110 electrically connected to said expansion slot 12 and said transmission interface 118. Through the circuits distributed on said circuit board, the external memory cards inserted in said expansion slot 12 may exchange data with the external PC system 16 via the transmission interface 118. Hereunder we will describe in general the circuit distribution on said circuit board 110.

Said circuit board 110 has a main controller 1110, which has a detecting and determining module 1114 and a bridging module 1112. The support of said main controller 1110 to said module 1114 and 1112 may be implemented with internal physical circuit or firmware burned in it. The object of detecting the module 1114 is to determine whether an external memory card has been inserted in the expansion slot 12 and, if there is a memory card inserted, to determine the type of the memory card. The bridging module 1112 delivers signal-forwarding function and thus serves as a communication and transmission medium between the main body 10 of the storage device and the external memory cards (or the external PC system 16).

When the transmission interface 118 on the main body 10 is directly coupled to a connection port 160 of the external PC system 16, the PC system 16 will transfer operation power signals and data/control signals to the main body 10 of the storage device according to the standard interface protocol. At this time, if any external memory card is inserted in the expansion slot 12 of the multifunctional flash memory drive, the detecting and determining module 1114 in said main controller 1110 will, according the circuit assigned, detect and determine the type of said external memory card, and then enable data exchange between the PC system 16 and said external memory card under the help of the data forwarding function of said bridging module 1112.

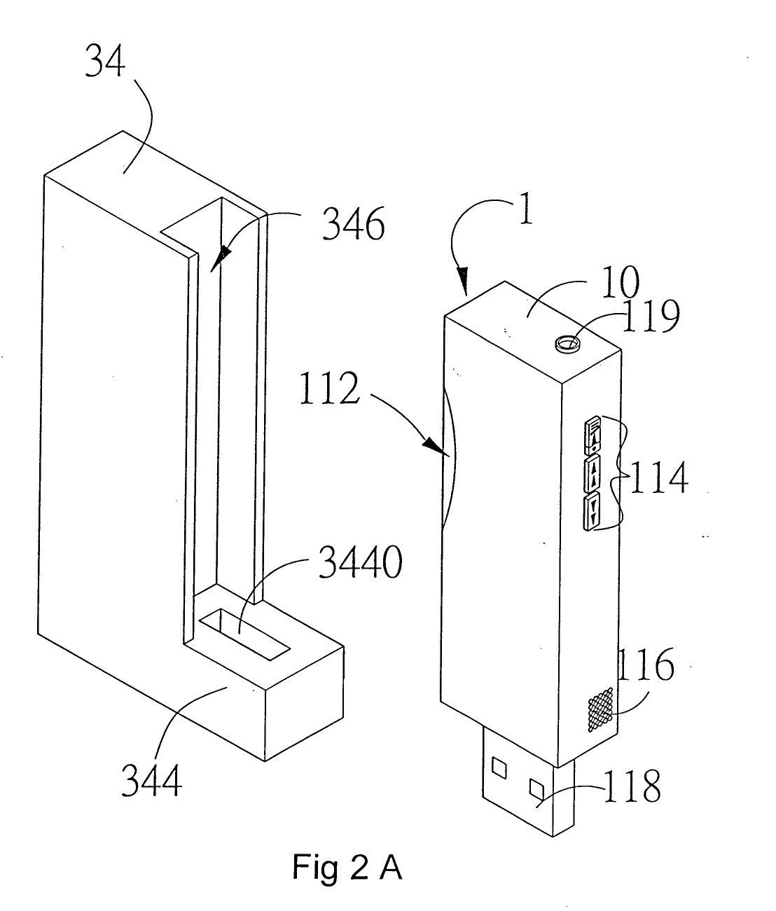

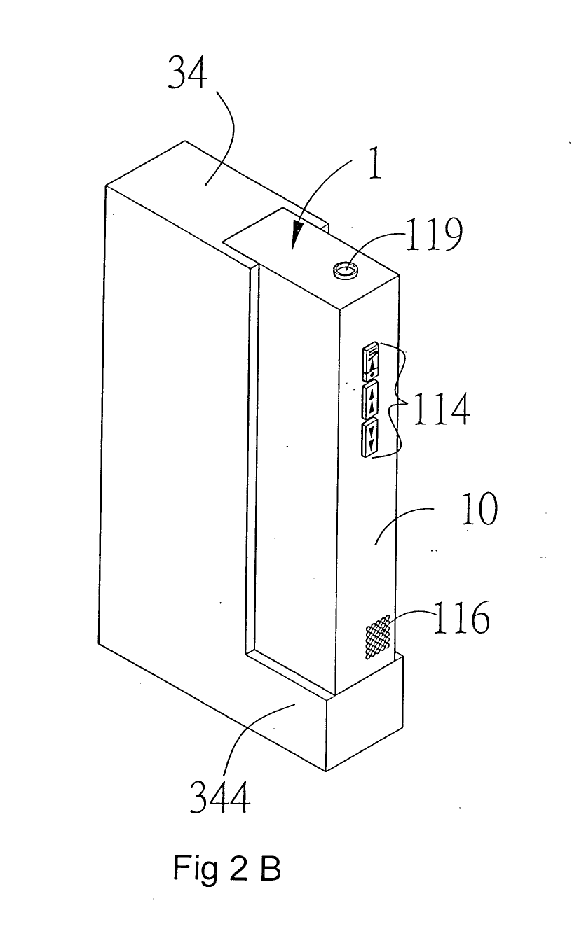

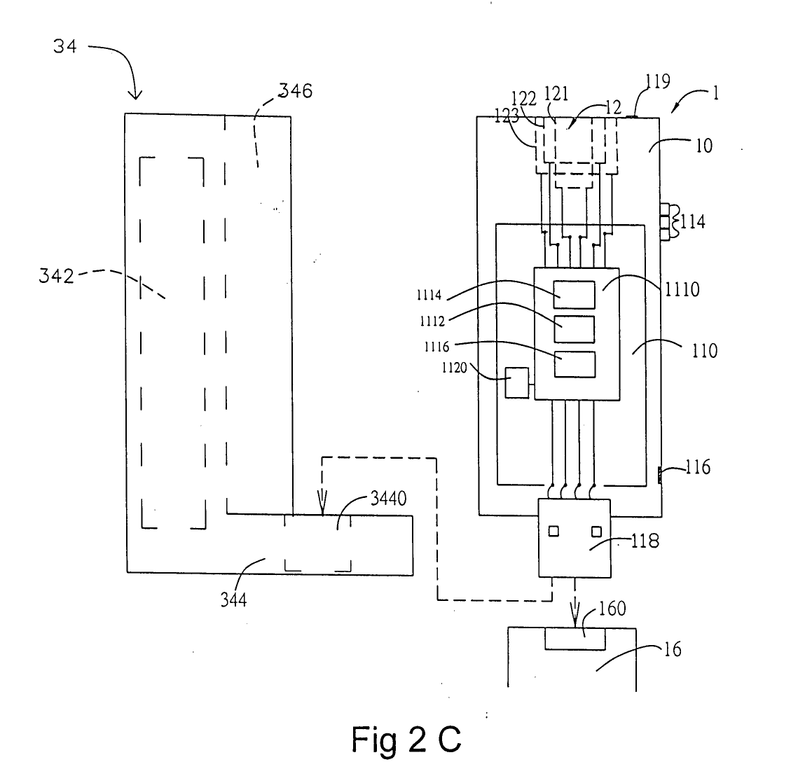

FIG. 2A˜2C show another preferred embodiment of the multifunctional flash memory drive 1 implemented according to the invention, wherein said device comprises a main body 10 and an expansion slot 12. Further, said main body 10 is designed on the basis of a MP3 player, with an expansion slot 12 and an insertion end 112 (similar to those in above embodiment) added. Thus the main body 10 may support the mini memory cards described above. Hereunder we will not discuss the expansion slot 22 in detail.

Please see FIG. 2C, wherein the main body 10 has an internal circuit board 110 electrically connected to said expansion slot 12, a transmission interface 118, an output unit including a earphone jack 119 and a microphone 116, and an input unit (including a man-machine interface & wireless remote control interface 114 and a microphone 116). All of those components are electrically connected to the circuits on the circuit board 110 in the main body 10. Through circuit branches and elements distributed on said circuit board 110, the main body 10 may play the digital audio content stored in the external memory cards inserted in the expansion slot 12 or convert external analog audio content (e.g., sound in the air or sound played by a FM radio) into digital audio data and stored it in said external memory cards.

There is a main controller 1110 on the circuit board 110, and the main controller 1110 has a detecting and determining module 1114, a bridging module 1112, and audio recording/playing module 1116. Wherein said detecting and determining module 1114 may detect and determine the type of the memory cards inserted in said expansion slot 12; the bridging module 1112 delivers signal forwarding function and serves as a communication and transmission medium between the circuit board 110 and the external memory cards; the audio recording and playing module 1116 may record and play audio data in WMV and/or MP3 format. Furthermore, during the recording process, at least A/D conversion and encoding will be done. In contrast, during the playing process, at least decoding, D/A conversion, and amplifying will be done. With said main controller 1110 processing audio data, said I/O units recording and playing audio data, and said transmission interface 118 transfer operation power, the main body 10 may retrieve audio data stored in the external memory cards inserted in said expansion slot 12 and play audio decoded, converted, and amplified by the output unit, or, the main body 10 may also convert and encode audio from the input unit and then store the processed data into the memory cards inserted in said expansion slot 12.

In the current embodiment, the transmission interface 1118 may a plug-type USB interface, IEEE1394 interface, or any other high-speed interface. Thus the transmission interface 118 may be coupled directly to the external equipment end without any wiring. Wherein said external equipment end may be a PC system 16 that delivers power necessary for operation of the storage device as well as digital audio data (as shown in FIG. 2C) or a separate power supply unit 34 that merely delivers power (as shown in FIGS. 2A and 2B, wherein the two drawings show the multifunctional flash memory drive detached/coupled to a separate power supply unit 34, respectively).

Please see FIGS. 2A and 2B, wherein the separate power supply unit 34 may be equipped with an USB or IEEE1394 interface socket 3440 on its seat 344 (depending on the type of the system interface on the main body 10). Said separate power supply unit 34 may be of integral design or separate design, and it has an embedded battery cartridge (with battery) (e.g., the battery cartridge 342 as shown in FIG. 2C) and an interface socket 3440 electrically connected to the battery cartridge. Said interface socket 3440 is designed to couple with the transmission interface 118 of said multifunctional flash memory drive 1 to deliver power for operation (e.g., play audio) of the latter. There is a guide groove 346 on one side of the seat 344 of said power supply unit 34 to guide the multifunctional flash memory drive 1 to be fixed accurately onto the seat 344 and make the multifunctional flash memory drive 1 coupled to the separate power supply unit 34 more closely and free from loose due to shock.

Please see FIG. 2C, wherein the multifunctional flash memory drive 1 may also exchange data with the PC system 16 via the transmission interface 118 on the main body 10. Said PC system 16 may utilize USB or IEEE1394 protocol and deliver power necessary for the operation of the storage device via its interface socket 160. In addition, the bridging module 1112 of the main controller 1110 on the circuit board 110 may also serve as a communication bridge between the multifunctional flash memory drive 1 and the PC system 16, thus the PC system 16 may exchange audio data with the memory cards inserted in the expansion slot 12 via the interface socket 160.

The multifunctional flash memory drive 1 described in above embodiment may also be equipped with a embedded flash memory 1120 on the circuit board 110 in the main body 10, said embedded flash memory 1120 may be used to store various data, including MP3 audio data, images and/or texts, so as to enhance functionality of the storage device (i.e., the user may choose to store data in the external memory cards and/or the embedded flash memory).

The present invention is disclosed as above with preferred embodiments. However, it is noted that above embodiments shall not constitute any limitation to the invention. Any skilled in this art may carry out modifications or embellishments to the embodiments without escaping the spirit and scope of the invention. Therefore, the scope of the invention is solely defined with the attached claims. Any embodiment implemented with equivalent modifications or embellishments to the invention (e.g., separate said bridging module, said detecting and determining module, and/or said audio recording and playing module from the main controller) shall fall in the scope of the invention.

1. A multifunctional flash memory drive, comprising a main body with a transmission interface and an expansion slot, said main body having an internal circuit board electrically connected to said expansion slot, said main body having at least an external input unit, an audio output unit and a transmission interface electrically connected to said circuit board; wherein said main body has an insertion end at one end, said insertion end extends towards the other end of the main body to form an enclosed space, a plurality of sockets are formed in a stack way in the direction vertical to said extension plane to accommodate memory cards of different specifications; said main body may record and store audio data into said external memory cards inserted in said expansion slot, or play the audio data stored in said external memory cards.

2. A multifunctional flash memory drive according to claim 1, wherein said transmission interface is designed into a plug form and coupled directly to the external equipment end without any wire.

3. A multifunctional flash memory drive according to claim 1 or 2, wherein said transmission interface is an USB interface, an IEEE1394 interface, or any other high-speed transmission interface.

4. A multifunctional flash memory drive according to claim 1, wherein said circuit board has a main controller on it, and said main controller comprises:
a detecting and determining module to detect and determine the type of the external memory cards inserted in said expansion slot;
a bridging module, which serves as the transmission medium between said main body and the expansion slot or the external equipment end, and
an audio recording and playing module capable of recording and playing audio.

5. A multifunctional flash memory drive according to claim 4, wherein said audio recording and playing module delivers encoding and decoding, D/A conversion, and amplification functions.

6. A multifunctional flash memory drive according to claim 1, wherein said main body is connected to a preset external equipment end, which may be a separate power supply unit comprising an internal battery cartridge with a battery and an interface socket electrically connected to said battery cartridge; said interface socket is coupled to the transmission interface of said multifunctional flash memory drive to deliver power necessary for operation of said multifunctional flash memory drive.

7. A multifunctional flash memory drive according to claim 6, wherein said external equipment end may be a PC system with an interface socket; said interface socket is coupled to the transmission interface of said multifunctional flash memory drive to deliver power necessary for operation of said multifunctional flash memory drive and exchange audio data with the external memory cards inserted in said expansion slot.

8. A multifunctional flash memory drive according to claim 1, wherein said circuit board is equipped with at least an embedded flash memory on it, said embedded flash memory serves as a storage medium for audio data.

9. A multifunctional flash memory drive according to claim 1, wherein said memory cards include MS series and/or SD cards and/or MMC cards and/or SM cards and/or xD cards and/or other mini memory cards.
